(19) United States
(12) Patent Application Publication
(10) Pub. No.: US 2025/0098540 A1
(43) Pub. Date: Mar. 20, 2025

(54) PIEZOELECTRIC LAMINATE AND PIEZOELECTRIC ELEMENT

(71) Applicant: FUJIFILM CORPORATION, Tokyo (JP)

(72) Inventors: Hiroyuki KOBAYASHI, Kanagawa (JP); Seigo NAKAMURA, Kanagawa (JP)

(21) Appl. No.: 18/805,553

(22) Filed: Aug. 15, 2024

(30) Foreign Application Priority Data
Sep. 14, 2023 (JP) 2023-149248

(51) Int. Cl. H10N 30/072; H10N 30/00; H10N 30/076; H10N 30/50; H10N 30/853

(52) U.S. Cl. CPC H10N 30/072; H10N 30/076; H10N 30/50; H10N 30/708; H10N 30/8554

(57) ABSTRACT

A piezoelectric laminate comprise: a substrate, a lower electrode layer and a piezoelectric film, in which in a case where an upper electrode layer is formed on the piezoelectric film, and a voltage applied between the upper electrode layer and the lower electrode layer is swept, in a current-voltage curve showing a change in a current with respect to a change in the voltage, which is obtained in a case where with the lower electrode layer being grounded and the upper electrode layer being used as a drive electrode, an applied voltage to the piezoelectric film is gradually increased from 0 V to a positive side and then gradually decreased from the positive side to a negative side via 0 V, the number of peaks during an increase of the voltage and the number of peaks during a decrease of the voltage are different from each other.

### CROSS REFERENCE TO RELATED APPLICATIONS

This application claims priority from Japanese Application No. 2023-149248, filed on Sep. 14, 2023, the entire disclosure of which is incorporated herein by reference.

### BACKGROUND

### 1. Technical Field

The present disclosure relates to a piezoelectric laminate and a piezoelectric element.

### 2. Related Art

As a material having excellent piezoelectric characteristics and excellent ferroelectricity, there is known a perovskite-type oxide such as lead zirconate titanate (Pb(Zr,Ti)O₃, hereinafter referred to as PZT). A piezoelectric body consisting of a perovskite-type oxide is applied as a piezoelectric film in a piezoelectric element comprising a lower electrode, a piezoelectric film, and an upper electrode on a substrate. This piezoelectric element has been developed into various devices such as a memory, an inkjet head (an actuator), a micromirror device, an angular velocity sensor, a gyro sensor, a piezoelectric micromachined ultrasonic transducer (PMUT), and an oscillation power generation device.

JP2009-71295A, JP2014-60330A, and the like disclose that in a PZT-based perovskite-type oxide, a piezoelectric film having high aligning properties and good piezoelectric performance can be realized by adding niobium (Nb) to a B site. WO2015/146607A discloses that piezoelectric performance of a piezoelectric film produced by a sol-gel method can be improved by adding manganese (Mn) in addition to Nb.

### SUMMARY

From the viewpoint of a device operation and reliability, a further increase in withstand voltage and reliability of a piezoelectric film is desired, and thus research and development of a piezoelectric film in which the withstand voltage and the reliability are increased by controlling a surface roughness and the like in addition to a composition has been carried out.

The technology of the present disclosure has been made in view of the above circumstances, and an object of the present disclosure is to provide a piezoelectric laminate and a piezoelectric element which have higher withstand voltage and reliability than those in the related art.

The present disclosure relates to a piezoelectric laminate comprising: a substrate; and a lower electrode layer and a piezoelectric film containing a perovskite-type oxide as a main component provided in this order on the substrate, in which in a case where an upper electrode layer is formed on the piezoelectric film, and a voltage applied between the upper electrode layer and the lower electrode layer is swept, in a current-voltage curve showing a change in a current with respect to a change in the voltage, which is obtained in a case where with the lower electrode layer being grounded and the upper electrode layer being used as a drive electrode, an applied voltage to the piezoelectric film is gradually increased from 0 V to a positive side and then gradually decreased from the positive side to a negative side via 0 V, the number of peaks during an increase of the voltage and the number of peaks during a decrease of the voltage are different from each other.

It is preferable that in a case where a peak half-width during an increase of the voltage is defined as Wu, and a peak half-width during a decrease of the voltage is defined as Wd in the current-voltage curve, Wu≥1.5×Wd is satisfied.

It is preferable that in a case where the number of peaks during an increase of the voltage is defined as NA, and the number of peaks during a decrease of the voltage is defined as NB, NA>NB.

It is preferable that the number of peaks NA during an increase of the voltage is greater than the number of peaks NB during a decrease of the voltage by 1.

It is preferable that the number of peaks NA during an increase of the voltage is 3, and the number of peaks NB during a decrease of the voltage is 2.

It is preferable that the perovskite-type oxide is represented by Pbₐ{(ZrₓTi₁₋ₓ)_{1-y}M_{y}}O₃, where M is a metal element selected from the group consisting of V, Nb, Ta, Sb, Mo, and W, and 0<x<1, 0<y<1, and 0.9≤a≤1.2 are satisfied.

It is preferable that M is Nb, and 0.08≤y≤0.15 is satisfied.

In the piezoelectric film, in a crystal grain size distribution acquired by an electron back scattered diffraction method, an average grain size obtained by performing weighted averaging with an area ratio of crystal grain sizes is preferably more than 0.25 m and more preferably 0.3 m or more. In addition, the average grain size is preferably 0.4 m or less.

It is preferable that a seed layer that is lattice-matched with the perovskite-type oxide is provided between the lower electrode layer and the piezoelectric film.

It is preferable that the seed layer has a lattice constant of 0.39 nm to 0.405 nm in a case of being regarded as a pseudo-cubic crystal.

It is preferable that the seed layer contains SrRuO₃ or BaRuO₃ as a main component.

The present disclosure relates to a piezoelectric element comprising: the piezoelectric laminate according to the present disclosure; and an upper electrode layer provided on the piezoelectric film of the piezoelectric laminate.

According to the technique of the present disclosure, it is possible to provide a piezoelectric laminate and a piezoelectric element having higher withstand voltage and reliability than those in the related art.

### BRIEF DESCRIPTION OF THE DRAWINGS

FIG. 1 is a schematic cross-sectional view showing a layer configuration of a piezoelectric laminate and a piezoelectric element of a first embodiment.

FIG. 2 is a schematic view of an I-V curve showing current-voltage (I-V) characteristics of a piezoelectric element of the embodiment.

FIG. 3 is a schematic cross-sectional view showing a layer configuration of a piezoelectric laminate and a piezoelectric element of a second embodiment.

FIG. 4 shows an I-V curve of Example 3.

FIG. 5 shows an I-V curve of Comparative Example 1.

FIG. 6 is an example of an image pattern of crystal grains on a surface of a piezoelectric film acquired by an EBSD method.

### DESCRIPTION OF EMBODIMENTS

Hereinafter, an embodiment according to the present disclosure will be described with reference to the drawings. In the drawings below, a layer thickness of each of layers and a ratio thereof are appropriately changed and drawn for easy visibility, and thus they do not necessarily reflect the actual layer thickness and ratio. In the present specification, a numerical range expressed using “to” means a range that includes preceding and succeeding numerical values of “to” as a lower limit value and an upper limit value, respectively. In numerical ranges that are described stepwise in the present disclosure, an upper limit value or a lower limit value described in a certain numerical range may be replaced with an upper limit value or a lower limit value of another numerical range described stepwise. In addition, in the numerical ranges described in the present disclosure, an upper limit value or a lower limit value described in a certain numerical range may be replaced with values shown in Examples.

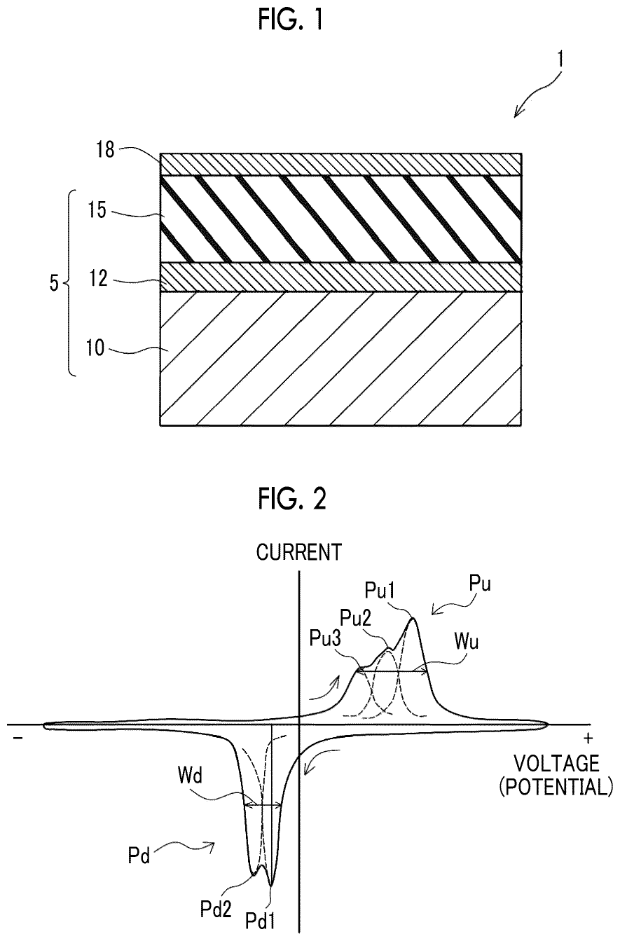

FIG. 1 is a schematic cross-sectional view showing a layer configuration of a piezoelectric laminate 5 and a piezoelectric element 1 having the piezoelectric laminate 5, according to an embodiment. As shown in FIG. 1, the piezoelectric element 1 has the piezoelectric laminate 5 and an upper electrode layer 18. The piezoelectric laminate 5 has a substrate 10; and a lower electrode layer 12 and a piezoelectric film 15 containing a perovskite-type oxide as a main component, which are laminated in order on the substrate 10. Here, “lower” and “upper” do not respectively mean top and bottom in a vertical direction. An electrode disposed on the substrate 10 side with the piezoelectric film 15 being interposed is merely referred to as the lower electrode layer 12, and an electrode disposed on a side opposite to the substrate 10 with respect to the piezoelectric film 15 is merely referred to as the upper electrode layer 18.

The substrate 10 is not particularly limited, and examples thereof include silicon, glass, stainless steel, yttrium-stabilized zirconia, alumina, sapphire, silicon carbide, or other substrates. As the substrate 10, a laminated substrate such as a thermal oxide film-attached silicon substrate having a SiO₂ oxide film formed on a surface of a silicon substrate may be used. Further, as the substrate 10, a resin substrate such as polyethylene terephthalate (PET), polyethylene naphthalate (PEN), polyimide, and the like may be used.

The lower electrode layer 12 is paired with the upper electrode layer 18 and is an electrode for applying a voltage to the piezoelectric film 15. The main component of the lower electrode layer 12 is not particularly limited, and examples thereof include metals such as gold (Au), platinum (Pt), iridium (Ir), ruthenium (Ru), titanium (Ti), molybdenum (Mo), tantalum (Ta), and aluminum (Al) or metal oxides thereof, and combinations thereof. In addition, indium tin oxide (ITO) or the like may be used. The lower electrode layer 12 may be a single layer or may have a laminated structure consisting of a plurality of layers. In a case where the lower electrode layer 12 has a laminated structure, it is also preferable to have a configuration in which an adhesion layer such as Ti, TiW, or ZrO₂ is provided on the substrate 10 side in addition to a conductive layer consisting of the above-described material.

A layer thickness of the lower electrode layer 12 is not particularly limited, and is preferably about 50 nm to 300 nm and more preferably 100 nm to 300 nm as a whole.

The upper electrode layer 18 is paired with the lower electrode layer 12 and is an electrode for applying a voltage to the piezoelectric film 15. The main component of the upper electrode layer 18 is not particularly limited, and examples thereof include metals such as Au, Pt, Ir, Ru, Ti, Mo, Ta, and Al or metal oxides thereof, and combinations thereof. In addition, indium tin oxide (ITO), LaNiO₃, SrRuO₃, or the like may be used. The upper electrode layer 18 may be a single layer or may have a laminated structure consisting of a plurality of layers. It is noted that from the viewpoint of further suppressing oxygen diffusion from the piezoelectric film 15, at least a region of the upper electrode layer 18 which is in contact with the piezoelectric film 15 is preferably an oxide electrode.

A layer thickness of the upper electrode layer 18 is not particularly limited, and is preferably about 50 nm to 300 nm and more preferably 100 nm to 300 nm.

FIG. 2 is a schematic view of a current-voltage (I-V) curve acquired by grounding the lower electrode layer 12 and applying a sweep voltage to the piezoelectric film 15 using the upper electrode layer 18 as a drive electrode. As shown in FIG. 2, in the piezoelectric film 15, the number of current peaks (hereinafter, referred to as the number of peaks) is different between during an increase of the voltage and during a decrease of the voltage in the I-V curve. The sweeping of an applied voltage is performed by increasing a potential applied to the upper electrode layer 18 from 0 V to a positive side and then decreasing the potential from the positive side to a negative side via 0 V. In the I-V curve, a case where a positive potential is applied to the upper electrode layer 18 is shown as a positive voltage, and a case where a negative potential is applied to the upper electrode layer 18 is shown as a negative voltage. The I-V curve is acquired, for example, by changing the voltage applied to the upper electrode layer 18 from 0 V to +40 V to −40 V to 0 V with a triangular wave of 10 Hz and measuring a change in a current value at that time. In a case where one period of the triangular wave that changes from 0 V to +40 V to −40 V to 0 V is set as one cycle, data may be unstable in a first cycle, but, generally, a curve that stably exhibits substantially the same behavior is obtained from a second cycle. In a case of counting the number of peaks, a stable I-V curve is used. For example, data of a third cycle is used.

In the I-V curve for the piezoelectric film 15, in a case where a peak half-width during an increase of the voltage is defined as Wu, and a peak half-width during a decrease of the voltage is defined as Wd, it is preferable that Wu≥1.5×Wd.

In a case where the number of peaks during an increase of the voltage is defined as NA, and the number of peaks during a decrease of the voltage is defined as NB in the I-V curve, it is preferable that NA>NB. In the example shown in FIG. 2, three peaks Pu1, Pu2, and Pu3 occur during an increase of the voltage, and two peaks Pd1 and Pd2 occur during a decrease of the voltage. That is, the number of peaks NA during an increase of the voltage is 3, and the number of peaks NB during a decrease of the voltage is 2.

As shown in FIG. 2, the peak half-width Wu is a half-width in a case where the entirety including three peaks Pu1, Pu2, and Pu3 is regarded as one peak Pu, and the peak half-width Wd is a half-width in a case where the entirety including two peaks Pd1 and Pd2 is regarded as one peak Pd. As described above, in a case where each of the peak half-width Wu during an increase of the voltage or the peak half-width Wd during a decrease of the voltage in the I-V curve includes a plurality of peaks, the peak half-width Wu or the peak half-width Wd is defined as a full width at half maximum of one wide peak including the plurality of peaks.

The number of peaks included in one wide peak is obtained as follows. A smoothing process of removing noise is performed on the acquired I-V curve, and in the smoothed I-V curve, for example, the number of points at which a derivative f₁′(x) in a case where a curve during an increase of the voltage is expressed by a function f₁(x) is 0 is defined as the number of peaks during an increase of the voltage. Similarly, the number of points at which a derivative f₂′(x) in a case where a curve during a decrease of the voltage is expressed by a function f₂(x) is 0 is defined as the number of peaks during a decrease of the voltage. Alternatively, peak fitting and peak separation may be performed by assuming a normal distribution or a log-normal distribution for the smoothed I-V curve. The number of peaks can be determined by using commercially available data analysis software (OriginPro or the like).

According to JP2010-16011A, an inflection point in a polarization-electric field (P-E) hysteresis curve means that a polarization reversal or a phase transition of 180° occurs. Further, since the inflection point of the P-E hysteresis curve corresponds to a current peak in the I-V curve, the current peak is considered to indicate that the polarization reversal or the phase transition of 180° occurs. In general, the number of peaks is the same between during an increase of the voltage and during a decrease of the voltage.

Like the piezoelectric film 15 in the present embodiment, a piezoelectric film in which the number of peaks is different between during an increase of the voltage and during a decrease of the voltage is obtained by performing reverse sputtering on a deposition surface before the film formation, and then performing the film formation. The piezoelectric film 15 obtained in this manner has strong adhesiveness. The strong adhesiveness of the piezoelectric film 15 means that a stress is large. In the piezoelectric film 15 having a large stress, it is presumed that a transition phase is formed due to relaxation of a substrate stress upon a phase transition occurring during an increase of the voltage, and the formation of the transition phase occurs as one peak in the I-V curve. On the other hand, during a decrease of the voltage, the stress is released together with the phase transition, and thus it is considered that the peak does not occur. In this way, in a case where the number of peaks during an increase of the voltage is larger than the number of peaks during a decrease of the voltage by 1, that is, in a case of NA=NB+1, it is presumed that one peak as a difference is related to the substrate stress.

For example, three peaks during an increase of the voltage as shown in FIG. 2 are assumed to be associated with a phase transition from tetragonal a-axis orientation to c-axis orientation, a polarization reversal of 180°, and the occurrence of the above-described transition phase due to substrate stress, and two peaks during a decrease of the voltage are assumed to be associated with a phase transition from tetragonal c-axis orientation to a-axis orientation and a polarization reversal of 180°.

In addition, in a case where a phase transition from a tetragonal crystal to a rhombohedral crystal occurs with a change in the voltage, the number of peaks increases from that shown in FIG. 2. In addition, generally, one peak occurs for one phase transition. However, there is a case where two or more peaks overlap and appear substantially as one peak. However, here, as described above, the number of points where the derivative of the curve is 0 is regarded as the number of peaks.

As described above, the piezoelectric film 15 of the present disclosure contains a perovskite-type oxide as a main component. Here, “contains a perovskite-type oxide as a main component” means that the perovskite-type oxide occupies 80 mol % or more of the piezoelectric film. It is preferable that the piezoelectric film 15 consists of 100 mol % of the perovskite-type oxide (however, containing unavoidable impurities).

The perovskite-type oxide is preferably a lead zirconate titanate (PZT)-based oxide that contains lead (Pb), zirconium (Zr), titanium (Ti), and oxygen (O).

In particular, it is preferable that the perovskite-type oxide is a compound represented by the following General Formula (1), which contains an additive M in the B site of PZT.

Pbₐ{(ZrₓTi₁₋ₓ)_{1-y}M_{y}}O₃ (1)
Here, M is preferably one or more elements selected from vanadium (V), niobium (Nb), tantalum (Ta), antimony (Sb), molybdenum (Mo), and tungsten (W). Here, it is preferable that 0<x<1, 0<y<1, and 0.9≤a≤1.2, and it is more preferable that 0.08≤y≤0.15. Further, in General Formula (1), regarding Pb:{(ZrₓT₁₋ₓ)_{1-y}M_{y}}:O, a reference ratio is 1:1:3; however, the ratio may deviate within a range in which a perovskite structure can be obtained.

M may be a single element such as V only or Nb only or may be a combination of two or three or more elements, such as a mixture of V and Nb or a mixture of V, Nb, and Ta. In a case where M is these elements, a very high piezoelectric constant can be realized in combination with Pb of an A-site element.

In a case where the piezoelectric film 15 is formed as a film of a sputtered film formed by a vapor-phase growth method such as sputtering, it is possible to obtain a piezoelectric film having a very high piezoelectric constant.

It is said that, in the PZT-based perovskite-type oxide, high piezoelectric characteristics are exhibited at a morphotropic phase boundary (MPB) and its vicinity. Zr:Ti (molar ratio) of around 52/48 is an MPB composition, and in the above general formula, the MPB composition or its vicinity is preferable. The “MPB or its vicinity” refers to a region in which a phase transition occurs in a case where an electric field is applied to the piezoelectric film. Specifically, Zr:Ti (molar ratio) is preferably in a range of 45:55 to 55:45, that is, in a range of x=0.45 to 0.55.

A film thickness of the piezoelectric film 15 is preferably 0.2 μm or more and 5 μm or less, and more preferably 1 m or more.

In the piezoelectric film 15, in a crystal grain size distribution acquired by an electron back scattered diffraction (EBSD) method, an average grain size obtained by performing weighted averaging with an area ratio of crystal grain sizes is preferably 0.3 m or more.

As described above, the piezoelectric laminate 5 of the present embodiment comprises: the substrate 10; and the lower electrode layer 12 and the piezoelectric film 15 containing a perovskite-type oxide as a main component provided in this order on the substrate 10, in which in a case where the upper electrode layer 18 is formed on the piezoelectric film 15, and a voltage applied between the upper electrode layer 18 and the lower electrode layer 12 is swept, in the I-V curve showing a change in a current with respect to a change in the voltage, which is obtained in a case where with the lower electrode layer 12 being grounded and the upper electrode layer 18 being used as a drive electrode, an applied voltage to the piezoelectric film 15 is gradually increased from 0 V to a positive side and then gradually decreased from the positive side to a negative side via 0 V, the number of peaks during an increase of the voltage and the number of peaks during a decrease of the voltage are different from each other. The present inventors have found that the piezoelectric film 15 in which the number of current peaks in the I-V curve is different between during an increase of the voltage and during a decrease of the voltage as described above exhibits high withstand voltage and reliability as compared to the piezoelectric film in which the number of peaks is the same between during an increase of the voltage and during a decrease of the voltage (see Examples described later). As described above, it is considered that high withstand voltage and reliability can be obtained by increasing a stress between the substrate 10 and the piezoelectric film 15 as compared to the related art.

The piezoelectric laminate 5 and the piezoelectric element 1 may include other layers such as an adhesion layer and a seed layer, in addition to the lower electrode layer 12 and the piezoelectric film 15.

### Second Embodiment

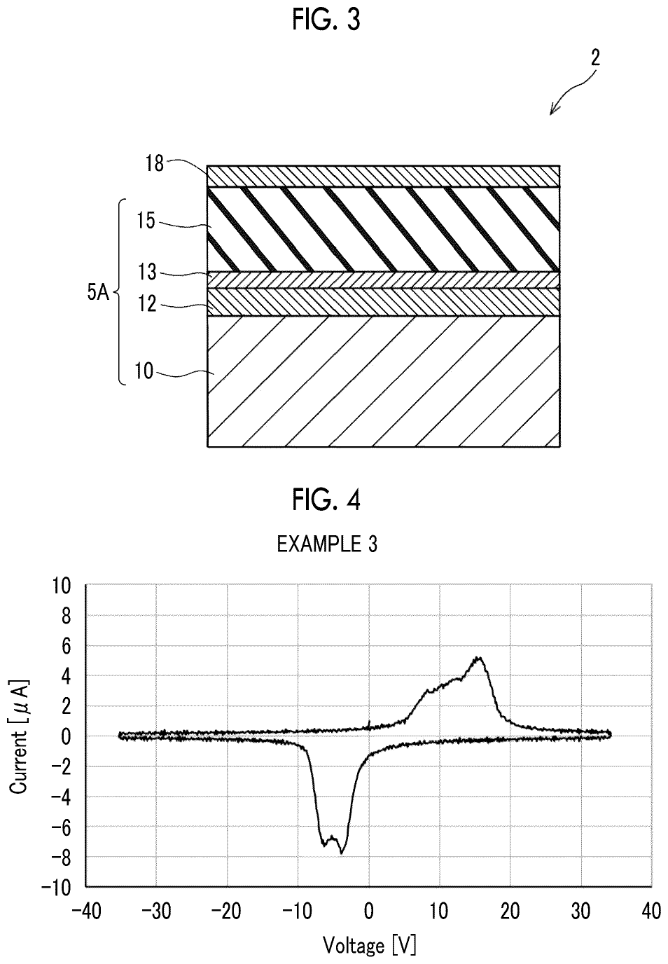

FIG. 3 is a schematic cross-sectional view of a piezoelectric element 2 of a second embodiment. The same constituent elements as those of the piezoelectric element 1 of the first embodiment shown in FIG. 1 are denoted by the same reference numerals. The piezoelectric element 2 comprises the substrate 10 and a piezoelectric laminate 5A. The piezoelectric laminate 5A is different from the piezoelectric laminate 5 in that a seed layer 13 is provided between the lower electrode layer 12 and the piezoelectric film 15.

The seed layer 13 is lattice-matched with the perovskite-type oxide which is a main component of the piezoelectric film 15. By providing the seed layer 13, crystallinity of the piezoelectric film 15 to be formed on an upper layer can be improved. The piezoelectric film 15 formed on the seed layer 13 may be an epitaxial film that is epitaxially grown.

It is preferable that the seed layer 13 has a lattice constant of 0.39 nm to 0.405 nm in a case of being regarded as a pseudo-cubic crystal. In a case where the lattice constant is in this range, in particular, since the seed layer 13 is lattice-matched with the perovskite-type oxide which is Nb-added PZT, the crystallinity of the piezoelectric film 15 can be improved in a case where the piezoelectric film 15 formed on the upper layer is Nb-added PZT. The lattice constant of each layer can be measured by X-ray diffraction (XRD) analysis.

It is preferable that the seed layer 13 has conductivity. It should be noted that having conductivity means having electrical resistivity sufficient to function as an electrode. Here, it is regarded as having conductivity in a case where the electrical resistivity at 20° C. is 10⁻⁵ Ω·m or less. In a case where the seed layer 13 has conductivity, the seed layer 13 can function as an electrode for applying a driving voltage to the piezoelectric film 15 together with the lower electrode layer 12.

Examples of the main component of the seed layer 13 include SrRuO₃, BaRuO₃, and PbTiO₃. The above oxides illustrated as the second perovskite-type oxide have a lattice constant of 0.39 nm to 0.405 nm in a case of being regarded as a pseudo-cubic crystal. As the main component of the seed layer 13, SrRuO₃ or BaRuO₃ having high conductivity is particularly preferable.

The piezoelectric laminate 5A and the piezoelectric element 2 are different from the piezoelectric laminate 5 and the piezoelectric element 1 in that the seed layer 13 is provided between the lower electrode layer 12 and the piezoelectric film 15, but the other configurations are the same as those of the piezoelectric laminate 5 and the piezoelectric element 1, and thus the same effects can be obtained. Further, the piezoelectric laminate 5A and the piezoelectric element 2 include the seed layer 13, whereby an effect of further improving the piezoelectric constant can be obtained as compared to a case where the seed layer 13 is not provided.

The piezoelectric element 1 or 2 or the piezoelectric laminate 5 or 5A according to each of the above embodiments can be applied to an ultrasonic device, a mirror device, a sensor, a memory, and the like.

### Examples

Hereinafter, specific examples and comparative examples of the piezoelectric element according to the present disclosure will be described. First, a production method for a piezoelectric element of each example will be described. A sputtering device was used for film formation of each layer. The description of the production method will be made with reference to the reference numerals of the respective layers of the piezoelectric element 1 shown in FIG. 1.

Production Method A thermal oxide film-attached silicon substrate was used as the substrate 10.

An electrode layer-attached substrate was prepared in which an adhesion layer consisting of Ti and having a thickness of 20 nm, the lower electrode layer 12 consisting of Pt and having a thickness of 150 nm, and the seed layer 13 consisting of SrRuO₃ and having a thickness of 20 nm were sequentially laminated on a thermal oxide film of the substrate 10.

### Piezoelectric Film

A Nb-added PZT film was formed as the piezoelectric film 15 on the seed layer 13 under the following sputtering conditions. For film formation, a Nb-added PZT target was used. A target was used in which a Pb composition ratio=1.3, a Zr/Ti molar ratio is an MPB composition (Zr/Ti=52/48), that is, x=0.52, and a Nb composition ratio y=0.12. In each of the examples, a pretreatment under conditions shown in Table 1 was performed immediately before the film formation of the piezoelectric film 15. For example, in a case of Example 1, a substrate bias voltage was set to −40 V, and input power was set to 0.5 kW. A pretreatment time was set to 3 minutes. The conditions other than the substrate bias voltage and the input power shown in Table 1 were set to the same conditions as the sputtering conditions of the piezoelectric film. In Comparative Example 1, no pretreatment was performed, and in Comparative Example 2, the substrate bias voltage during the pretreatment was set to the same voltage as that during film formation.

### Sputtering Conditions for Piezoelectric Film

Distance between target and substrate: 100 mm
Target input power: 3 kW
Degree of vacuum (film formation pressure): 0.5 Pa
Atmosphere: Ar/O₂ mixture (0₂ volume fraction: 2.5%)
Set temperature of substrate: 550° C.
Substrate bias voltage: +40 V

### Upper Electrode Layer

An ITO layer having a thickness of 100 nm was formed as the upper electrode layer 18 on the piezoelectric film 15 of the above-described laminated substrate by sputtering.

### Formation of Electrode Pattern for Evaluation

A resist pattern was formed using photolithography before the film formation of the upper electrode layer 18, the upper electrode layer 18 was formed on the resist pattern by film formation, and an upper electrode pattern for evaluation was formed by lifting-off.

The laminates of Comparative Examples and Examples were prepared by the above-described steps.

TABLE 1

Pretreatment

| | Substrate Bias Voltage | Input Power |
|---|---|---|
| | V | kW |
| Comparative Example 1 | — | — |
| Comparative Example 2 | 40 | 0.5 |
| Example 1 | −40 | 0.5 |
| Example 2 | −60 | 0.5 |
| Example 3 | −80 | 0.5 |
| Example 4 | −100 | 0.5 |
| Example 5 | −100 | 0.2 |

### Preparation of Evaluation Samples

### Evaluation Sample 1

A strip-shaped portion of 2 mm×25 mm was cut out from the laminate to prepare a cantilever as an evaluation sample 1.

### Evaluation Sample 2

A portion of 25 mm×25 mm having, at a center of a surface of the piezoelectric film 15, the upper electrode layer 18 that had been patterned in a circular shape having a diameter of 400 m was cut out from the laminate and used as an evaluation sample 2.

### Measurement of Current-Voltage Characteristics

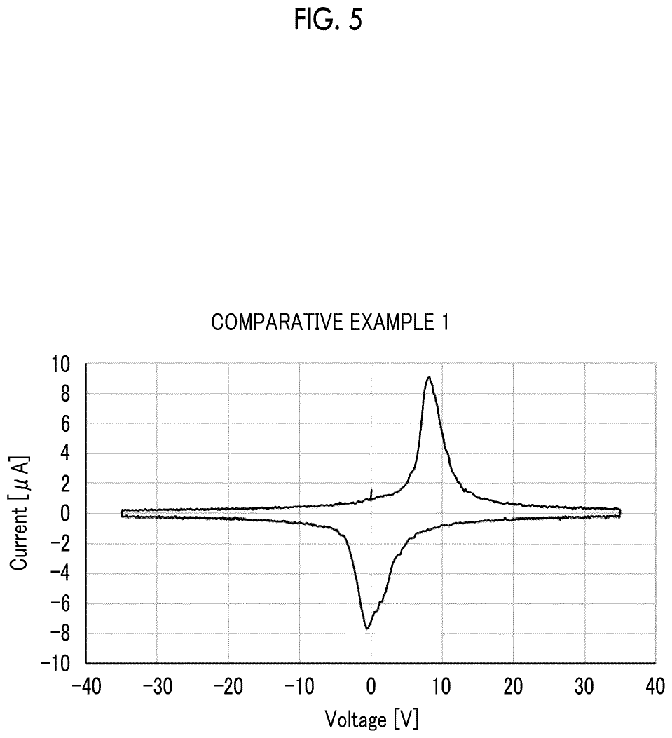

For the piezoelectric element of each of Examples and Comparative Examples, an I-V curve was measured using the evaluation sample 2. A ferroelectric characteristic evaluation system FEC10 manufactured by TOYO Corporation was used for the measurement. For the piezoelectric element of each of Examples and Comparative Examples, the lower electrode layer 12 was grounded, the potential applied to the upper electrode layer 18 was changed from 0 V to +40 V to −40 V to 0 V under a condition of a frequency of 10 Hz, and the I-V curve at that time was acquired. The measurement of the I-V curve was performed such that the change of the potential from 0 V to +40 V to −40 V to 0 V was set as one cycle and a coercive electric field value was determined from data of a third cycle. As already described, in the measurement of the I-V curve, a first cycle is unstable, and, generally, an I-V curve that stably exhibits substantially the same behavior is obtained from a second cycle. Here, for the sake of clarity, the data of the third cycle was used. A part of the acquired I-V curve is shown in FIG. 4 and FIG. 5. FIG. 4 shows an I-V curve of Example 3, and FIG. 5 shows an I-V curve of Comparative Example 1.

As shown in FIG. 4, in the I-V curve of Example 3, three peaks occur during an increase of the voltage, and two peaks occur during a decrease of the voltage. Meanwhile, as shown in FIG. 5, in the I-V curve of Comparative Example 1, there was only one peak in both during an increase of the voltage and during a decrease of the voltage. The number of peaks NA during an increase of the voltage and the number of peaks NB during a decrease of the voltage in each of Examples and Comparative Examples were as shown in Table 2.

### Measurement of Piezoelectric Constant

According to the method described in I. Kanno et al., Sensor and Actuator A 107 (2003) 68, a piezoelectric constant d₃₁ [pm/V] was measured using the cantilever, by using an applied voltage of a sine wave of −10 V±10 V, that is, an applied voltage in which a sine wave having an amplitude of 10 V is added to a bias voltage of −10 V. The measurement results are shown in Table 2.

The piezoelectric constant was evaluated according to the following standard, and the evaluation results are shown in Table 2 together.
A: 200 pm/V or more
B: 170 pm/V or more and less than 200 pm/V
C: Less than 170 pm/V

### Evaluation of Withstand Voltage

The withstand voltage (dielectric breakdown voltage) of each of Examples and Comparative Examples was measured. Using the evaluation sample 2, the lower electrode layer 12 was grounded, a negative voltage was applied to the upper electrode layer 18 at a change rate of −1 V/see, and a voltage at which a current of 1 mA or more flowed was regarded as the withstand voltage. Ten samples were prepared for each example, the measurements were carried out a total of 10 times, and an average value (absolute value) thereof is shown in Table 2 as the withstand voltage [V].

The withstand voltage was evaluated according to the following standard, and the evaluation results are shown in Table 2 together.
A: 100 V or more
B: 60 V or more and less than 100 V
C: less than 60 V

### Evaluation of Driving Stability (Reliability)

A time dependent dielectric breakdown (TDDB) test was carried out as an evaluation of driving stability of each of Examples and Comparative Examples. Using the evaluation sample 2, in an environment of 120° C., the lower electrode layer 12 was grounded, a voltage of −40 V was applied to the upper electrode layer 18, and a time (hr) taken from the start of the voltage application to the occurrence of dielectric breakdown was measured. The measurement results are shown in Table 2. The TDDB test was carried out for 2,000 hours, and those in which dielectric breakdown did not occur up to 2,000 hours are described as 2,000 in Table 2.

The reliability was evaluated according to the following standard, and the evaluation results are shown in Table 2 together.
A: 1000 hr or more
B: 700 hr or more and less than 1000 hr
C: Less than 700 hr

### Method of Measuring Crystal Grain Size

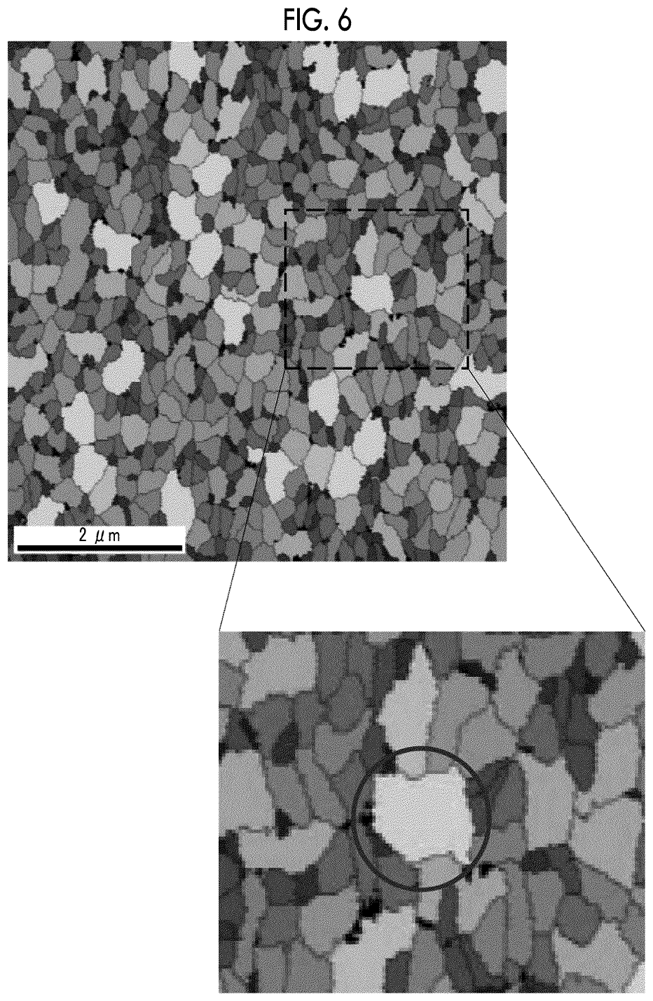

The surface of the piezoelectric film after the film formation, that is, the surface of the piezoelectric film before the film formation of the upper electrode, was measured by EBSD. As a measuring device, a scanning electron microscope (SEM): JSM-7001F manufactured by JEOL Ltd., and EBSD: OIM manufactured by TSL were used. FIG. 6 shows an image pattern of crystal grains on the surface of the piezoelectric film acquired by the EBSD method. The crystal grains were specified in the image pattern as shown in FIG. 6, the minimum circumscribed circle was obtained for each of the crystal grains, and a diameter of the circumscribed circle was obtained as the crystal grain size. The average grain size was calculated by performing weighted averaging with an area ratio of crystal grain sizes. The average grain size of each of Examples and Comparative Examples was as shown in Table 2.

In addition, in Table 2, the lowest evaluation result among the evaluations of the piezoelectric constant, the withstand voltage, and the reliability is shown as an overall evaluation for each of Examples and Comparative Examples.

TABLE 2

| | I-V Curve | | | | Piezoelectric Performance | | | | | | |
|---|---|---|---|---|---|---|---|---|---|---|---|
| | Number | | Half- | Crystal | | | | | | | Over- |
| | of | | Width | Grain | Piezoelectric | | Withstand | | | | all |
| | Peaks | | Ratio | Size | Constant | | Voltage | | Reliability | | Eval- |
| | NA | NB | Wu/Wd | μm | pm/V | Evaluation | V | Evaluation | hr | Evaluation | uation |
| Comparative | 1 | 1 | 0.7 | 0.25 | 200 | A | 50 | C | 500 | C | C |
| Example 1 | | | | | | | | | | | |
| Comparative | 1 | 1 | 1 | 0.24 | 200 | A | 50 | C | 500 | C | C |
| Example 2 | | | | | | | | | | | |
| Example 1 | 2 | 1 | 1.2 | 0.29 | 200 | A | 80 | B | 1000 | A | B |
| Example 2 | 3 | 2 | 1.5 | 0.3 | 200 | A | 100 | A | 1200 | A | A |
| Example 3 | 3 | 2 | 1.9 | 0.32 | 200 | A | 120 | A | 1500 | A | A |
| Example 4 | 3 | 2 | 2 | 0.35 | 200 | A | 150 | A | 2000 | A | A |
| Example 5 | 2 | 1 | 1.3 | 0.27 | 200 | A | 60 | B | 700 | B | B |

The piezoelectric constant was the same in Comparative Examples 1 and 2 and Examples 1 to 5. However, in Examples 1 to 5 in which the pretreatment was performed before film formation of the piezoelectric film by reversing positive and negative substrate bias voltages from those during the film formation, the withstand voltage and the reliability were significantly improved as compared to Comparative Examples 1 and 2. In such an element in which a high withstand voltage and reliability were obtained, the number of peaks NA during an increase of the voltage was greater than the number of peaks NB during a decrease of the voltage in the I-V curve, and the peak half-width Wu during an increase of the voltage was 1.2 times or more the peak half-width Wd during a decrease of the voltage. In a case where a ratio Wu/Wd of the peak half-width was 1.5 or more, higher withstand voltage and reliability were obtained.

All documents, patent applications, and technical standards described in the present specification are incorporated in the present specification by reference to the same extent as in a case where each document, patent application, and technical standard are specifically and individually noted to be incorporated by reference.

Furthermore, the following appendices will be disclosed in relation to the above-described embodiment.

### APPENDIX 1

A piezoelectric laminate comprising: a substrate; and a lower electrode layer and a piezoelectric film containing a perovskite-type oxide as a main component provided in this order on the substrate, in which in a case where an upper electrode layer is formed on the piezoelectric film, and a voltage applied between the upper electrode layer and the lower electrode layer is swept, in a current-voltage curve showing a change in a current with respect to a change in the voltage, which is obtained in a case where with the lower electrode layer being grounded and the upper electrode layer being used as a drive electrode, an applied voltage to the piezoelectric film is gradually increased from 0 V to a positive side and then gradually decreased from the positive side to a negative side via 0 V, the number of peaks during an increase of the voltage and the number of peaks during a decrease of the voltage are different from each other.

### APPENDIX 2

The piezoelectric laminate according to Appendix 1, in which in a case where a peak half-width during an increase of the voltage is defined as Wu, and a peak half-width during a decrease of the voltage is defined as Wd in the current-voltage curve, Wu≥1.5×Wd is satisfied.

### APPENDIX 3

The piezoelectric laminate according to Appendix 1 or 2, in which in a case where the number of peaks during an increase of the voltage is defined as NA, and the number of peaks during a decrease of the voltage is defined as NB, NA>NB is satisfied.

### APPENDIX 4

The piezoelectric laminate according to Appendix 3, in which the number of peaks NA during an increase of the voltage is greater than the number of peaks NB during a decrease of the voltage by 1.

### APPENDIX 5

The piezoelectric laminate according to Appendix 3, in which the number of peaks NA during an increase of the voltage is 3, and the number of peaks NB during a decrease of the voltage is 2.

### APPENDIX 6

The piezoelectric laminate according to any one of Appendices 1 to 5, in which the perovskite-type oxide is represented by Pbₐ{(ZrₓTi₁₋ₓ)_{1-y}M_{y}}O₃, where M is a metal element selected from the group consisting of V, Nb, Ta, Sb, Mo, and W, and 0<x<1, 0<y<1, and 0.9≤a≤1.2 are satisfied.

### APPENDIX 7

The piezoelectric laminate according to Appendix 6, in which the M is Nb, and 0.08≤y≤0.15 is satisfied.

### APPENDIX 8

The piezoelectric laminate according to any one of Appendices 1 to 7, in which in the piezoelectric film, in a crystal grain size distribution acquired by an electron back scattered diffraction method, an average grain size obtained by performing weighted averaging with an area ratio of crystal grain sizes is 0.3 m or more.

### APPENDIX 9

The piezoelectric laminate according to any one of Appendices 1 to 8, further comprising: a seed layer that is lattice-matched with the perovskite-type oxide between the lower electrode layer and the piezoelectric film.

### APPENDIX 10

The piezoelectric laminate according to Appendix 9, in which the seed layer has a lattice constant of 0.39 nm to 0.405 nm in a case of being regarded as a pseudo-cubic crystal.

### APPENDIX 11

The piezoelectric laminate according to Appendix 9 or 10, in which the seed layer contains SrRuO₃ or BaRuO₃ as a main component.

### APPENDIX 12

A piezoelectric element comprising: the piezoelectric laminate according to any one of Appendices 1 to 11; and an upper electrode layer provided on the piezoelectric film of the piezoelectric laminate.

What is claimed is:

1. A piezoelectric laminate comprising:
a substrate; and
a lower electrode layer and a piezoelectric film containing a perovskite-type oxide as a main component provided in this order on the substrate,
wherein in a case where an upper electrode layer is formed on the piezoelectric film, and a voltage applied between the upper electrode layer and the lower electrode layer is swept, in a current-voltage curve showing a change in a current with respect to a change in the voltage, which is obtained in a case where with the lower electrode layer being grounded and the upper electrode layer being used as a drive electrode, an applied voltage to the piezoelectric film is gradually increased from 0 V to a positive side and then gradually decreased from the positive side to a negative side via 0 V, the number of peaks during an increase of the voltage and the number of peaks during a decrease of the voltage are different from each other.

2. The piezoelectric laminate according to claim 1,
wherein in a case where a peak half-width during an increase of the voltage is defined as Wu, and a peak half-width during a decrease of the voltage is defined as Wd in the current-voltage curve, Wu≥1.5×Wd is satisfied.

3. The piezoelectric laminate according to claim 1,
wherein in a case where the number of peaks during an increase of the voltage is defined as NA, and the number of peaks during a decrease of the voltage is defined as NB, NA>NB is satisfied.

4. The piezoelectric laminate according to claim 3,
wherein the number of peaks NA during an increase of the voltage is greater than the number of peaks NB during a decrease of the voltage by 1.

5. The piezoelectric laminate according to claim 3,
wherein the number of peaks NA during an increase of the voltage is 3, and the number of peaks NB during a decrease of the voltage is 2.

6. The piezoelectric laminate according to claim 1,
wherein the perovskite-type oxide is represented by Pbₐ{(ZrₓTi₁₋ₓ)_{1-y}M_{y}}O₃,
where M is a metal element selected from the group consisting of V, Nb, Ta, Sb, Mo, and W, and
0<x<1, 0<y<1, and 0.9≤a≤1.2 are satisfied.

7. The piezoelectric laminate according to claim 6,
wherein the M is Nb, and 0.08≤y≤0.15 is satisfied.

8. The piezoelectric laminate according to claim 1,
wherein in the piezoelectric film, in a crystal grain size distribution acquired by an electron back scattered diffraction method, an average grain size obtained by performing weighted averaging with an area ratio of crystal grain sizes is 0.3 m or more.

9. The piezoelectric laminate according to claim 1, further comprising:
a seed layer that is lattice-matched with the perovskite-type oxide between the lower electrode layer and the piezoelectric film.

10. The piezoelectric laminate according to claim 9,
wherein the seed layer has a lattice constant of 0.39 nm to 0.405 nm in a case of being regarded as a pseudo-cubic crystal.

11. The piezoelectric laminate according to claim 9,
wherein the seed layer contains SrRuO₃ or BaRuO₃ as a main component.

12. A piezoelectric element comprising:
the piezoelectric laminate according to claim 1; and
an upper electrode layer provided on the piezoelectric film of the piezoelectric laminate.
